(19) United States
(12) Patent Application Publication
(10) Pub. No.: US 2024/0217216 A1
(43) Pub. Date: Jul. 4, 2024

(54) ULTRATHIN LAMINATED GLASS AND GLASS STIFFENERS FOR CORELESS PACKAGES

(71) Applicant: INTEL CORPORATION, SANTA CLARA, CA (US)

(72) Inventors: Kristof DARMAWIKARTA, Chandler, AZ (US); Tarek A. IBRAHIM, Mesa, AZ (US); Srinivas V. PIETAMBARAM, Chandler, AZ (US); Dilan SENEVIRATNE, Chandler, AZ (US); Jieying KONG, Chandler, AZ (US); Thomas HEATON, Gilbert, AZ (US); Whitney BRYKS, Tempe, AZ (US); Vinith BEJUGAM, Chandler, AZ (US); Junxin WANG, Gilbert, AZ (US); Gang DUAN, Chandler, AZ (US)

(21) Appl. No.: 18/091,028

(22) Filed: Dec. 29, 2022

(51) Int. Cl. B32B 17/10; B32B 7/12; B32B 17/02; B65D 85/48

(52) U.S. Cl. CPC B32B 17/10642; B32B 7/12; B32B 17/02; B65D 85/48; B32B 2260/04; B32B 2307/202; B32B 2457/00

(57) ABSTRACT

Embodiments disclosed herein include package substrates with glass stiffeners. In an embodiment, the package substrate comprises a first layer, where the first layer comprises glass. In an embodiment, the package substrate comprises a second layer over the first layer, where the second layer is a buildup film. In an embodiment, the package substrate further comprises an electrically conductive interconnect structure through the first layer and the second layer.

### TECHNICAL FIELD

Embodiments of the present disclosure relate to electronic packages, and more particularly to coreless architectures that include ultrathin laminated glass or glass stiffeners.

### BACKGROUND

In some client segments, low package thickness (also referred to as “z-height”) is a desirable design parameter. One such client segment where package thickness is a critical design parameter is in the mobile client segment (e.g., phones, tablets, and other mobile devices). In order to reduce z-height, reduced thickness package cores may be used. For example, organic cores with thicknesses down to approximately 200 μm have been proposed. However, even at 200 μm thick, the cores often do not leave enough room for package routing and/or breakout traces. One solution has been to move to thinner core materials. For example, glass cores have been proposed. While glass cores can provide the desired mechanical properties for thin packages, they suffer from difficulty in handling and assembly. That is, the glass cores may be easily broken during assembly.

Coreless solutions have also been proposed. Unfortunately, large form factors, higher layer count, etc. can lead to problems such as too much warpage. The high amount of warpage can lead to low yields and is not compatible with high volume manufacturing environments.

### BRIEF DESCRIPTION OF THE DRAWINGS

FIG. 1A is a cross-sectional illustration of a coreless package substrate that includes an ultrathin glass layer for reinforcement, in accordance with an embodiment.

FIG. 1B is a cross-sectional illustration of a coreless package substrate that includes a first ultrathin glass layer and a second ultrathin glass layer, in accordance with an embodiment.

FIGS. 2A-2K are cross-sectional illustrations depicting a process for forming a coreless package with an ultrathin glass layer for reinforcement, in accordance with an embodiment.

FIGS. 3A-3J are cross-sectional illustrations depicting a process for forming a coreless package with a pair of ultrathin glass layers for reinforcement, in accordance with an embodiment.

FIG. 4 is a cross-sectional illustration of a coreless package substrate with an embedded glass stiffener, in accordance with an embodiment.

FIGS. 5A-5I are cross-sectional illustrations depicting a process for forming a coreless package with an embedded glass stiffener, in accordance with an embodiment.

FIG. 6 is a cross-sectional illustration of a computing system with a coreless package substrate with an ultrathin glass layer, in accordance with an embodiment.

FIG. 7 is a schematic of a computing device built in accordance with an embodiment.

### EMBODIMENTS OF THE PRESENT DISCLOSURE

Described herein are coreless architectures that include ultrathin laminated glass or glass stiffeners, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, traditional packaging solutions that employ a core for reinforcement are limited in reductions to z-height. Even advanced solutions, such as glass cores, result in difficult handling and assembling considerations. Further, glass cores still may result in z-height values that are not compatible with advanced mobile client segments. For example, targeted z-heights for advanced mobile client segments may be approximately 350 μm or less. Even a 100 μm core will occupy a substantial portion of the allowable z-height.

Accordingly, there is a drive to enable coreless package substrates. Existing coreless technologies rely on buildup films that are reinforced with composite layers that include glass cloth or fibers embedded in an epoxy dielectric. However, when form factor (in the X-Y plane) and the number of layers needed for electrical routing are increased, the glass cloth reinforcement does not provide sufficient reinforcement to mitigate the high amount of warpage seen in such solutions. Therefore, embodiments disclosed herein include coreless package substrates that include glass sheet or glass stiffener reinforcements.

In the case of glass sheets, thin glass layers are integrated into the process flow in order to improve the mechanical properties of the coreless package substrate. The glass sheets may be referred to as being ultrathin in some embodiments. Particularly, ultrathin glass sheets may refer to thicknesses that are less than the thickness of common glass core solutions. For example, ultrathin glass sheets may have a thickness that is less than approximately 100 μm, less than approximately 50 μm, less than approximately 20 μm, or less than approximately 5 μm.

Glass sheets may be integrated into the stack using various material handling solutions. In one instance, glass sheets may be manufactured in a roll-to-roll configuration that allows for lamination of the glass sheet onto the stack. In another instance, a thicker glass sheet may be pressed/placed on the stack, and subsequently thinned down with an etching process, a polishing process or the like. For example, a glass sheet with a thickness over 100 μm may be easier to handle, and the thickness may be reduced to less than 50 μm after attached to the stack. In yet another embodiment, glass sheets may be placed on a carrier (e.g., a thicker glass carrier, a stainless steel carrier, or the like) for easier handling. Thicker sheets may be adhered to the carrier, and the thicker sheets may then be thinned to a desired thickness.

The glass sheets may be adhered to the stack using any suitable adhesive material. In one instance, standard buildup film (e.g., epoxy based organic dielectric material) may be sufficient to bind the incoming glass sheets to exiting substrate layers. The glass sheets may be compatible with patterning processes (e.g., laser assisted patterning processes) in order to form openings for vias through the glass sheet. This enables electrical routing through the thickness of the coreless package substrate. Embodiments may include one or more glass sheets integrated into the stack-up.

In the case of glass stiffeners, the coreless package substrate may be formed on a glass carrier. Voided regions of the redistribution layers (i.e., regions without electrical routing for signals or power) may then be removed to form openings through the redistribution layers. A glass stiffener may then be inserted into the openings. In one embodiment, the glass stiffener may be a ring that surrounds a perimeter of the package redistribution layers. A buildup film or the like may then be disposed over the glass stiffener and the redistribution layer in order to mechanically couple the two structures together.

While embodiments disclosed herein are particularly beneficial for coreless architectures, it is to be appreciated that cored architectures may also benefit from the inclusion of glass sheets in the buildup layers and/or glass stiffeners. That is, embodiments disclosed herein should not be interpreted as being limited to coreless architectures.

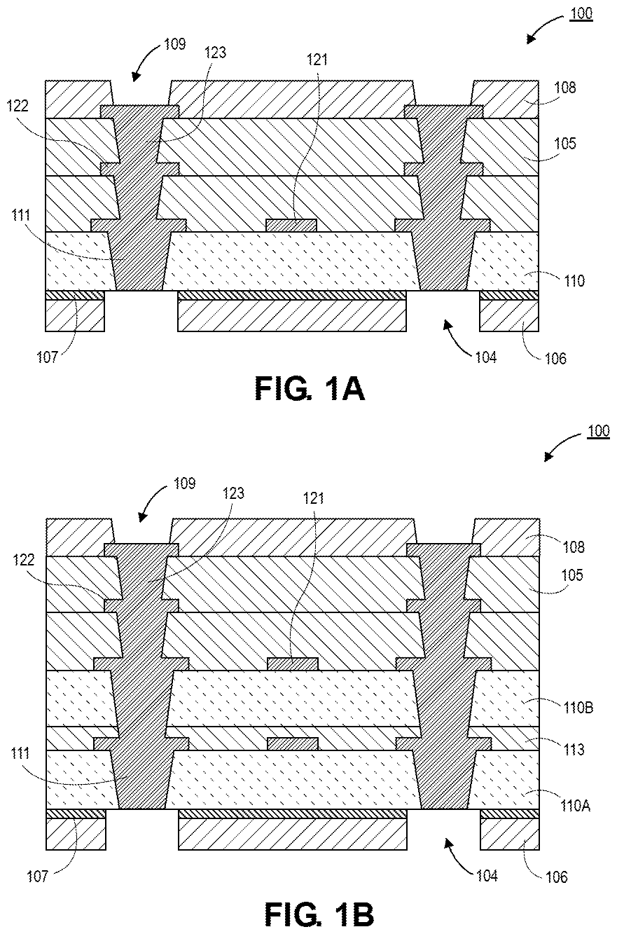

Referring now to FIG. 1A, a cross-sectional illustration of a package substrate 100 is shown, in accordance with an embodiment. In an embodiment, the package substrate 100 may be referred to as a coreless package substrate 100. A coreless package substrate 100 is a package substrate that does not have a traditional core layer, such as an organic core layer, a glass core layer, or the like. More generally, the coreless package substrate 100 may be a package substrate that does not include a reinforcement layer that is approximately 100 μm or greater. While glass sheets 110 are included in the package substrate 100, the glass sheets 110 are not considered to be cores since they have thicknesses that are less than approximately 100 μm. Further, the glass sheet 110 may be located at any point in the z-height of the package substrate 100.

In an embodiment, the package substrate 100 comprises a glass sheet 110 in the stack-up. In an embodiment, the glass sheet 110 may have a thickness that is approximately 100 μm or less, approximately 50 μm or less, approximately 20 μm or less, or approximately 5 μm or less. As used herein, “approximately” may refer to a range of values that are within ten percent of the stated value. For example, approximately 100 μm may refer to a range between 90 μm and 110 μm.

In an embodiment, the glass sheet 110 may be any suitable glass formulation. For example, the glass sheet 110 may be a borosilicate glass, a fused silica glass, or the like. In an embodiment, the glass sheet 110 may be a glass formulation that is compatible with a laser assisted patterning process. Laser assisted patterning processes may include laser exposure of regions of the glass. The exposed regions undergo a change to microstructure/phase that renders the exposed regions more susceptible to a wet etching chemistry. In an embodiment, vias 111 may be provided through a thickness of the glass sheet 110. The vias 111 may have tapered sidewalls in some embodiments.

In an embodiment with the glass sheet 110 at the bottom of the conductive routing, a solder resist 106 may be applied over the bottom of the glass sheet 110. The solder resist 106 may be adhered to the glass sheet 110 with an adhesive 107 in some embodiments. The solder resist 106 may include solder resist openings (SROs) 104 to expose a bottom surface of the vias 111.

In an embodiment, one or more buildup layers 105 may be provided over the glass sheet 110. The buildup layer 105 may include traditional buildup film. In some instances, the buildup layers 105 may include fiber reinforcement or glass cloth reinforcement. The buildup layers 105 may comprise conductive routing, such as traces 121, pads 122, and vias 123. The conductive routing may be formed with traditional patterning processes for package assembly (e.g., semi-additive processing (SAP) or the like). In an embodiment, a second solder resist 108 may be provided over the topmost buildup layer 105. The second solder resist 108 may include SROs 109 to provide access to the conductive routing in the package substrate 100.

Referring now to FIG. 1B, a cross-sectional illustration of a package substrate 100 is shown, in accordance with an additional embodiment. In an embodiment, the package substrate 100 in FIG. 1B may be substantially similar to the package substrate 100 in FIG. 1A, with the addition of a second glass sheet 110B above the first glass sheet 110A. In an embodiment, the second glass sheet 110B may be adhered to the first glass sheet 110A with an adhesive layer 113. In some embodiments, the adhesive layer 113 may be the same material as the buildup layers 105, though other adhesives may also be used in some embodiments.

In the illustrated embodiment, the glass sheets 110A and 110B are adjacent to each other. However, in other embodiments, one or more buildup layers 105 may be provided between glass sheets 110. Additionally, while two glass sheets are shown, it is to be appreciated that any number of glass sheets 110 may be included in the package substrate 100. While shown as having substantially similar thicknesses, in some embodiments, the first glass sheet 110A may have a different thickness than the second glass sheet 110B.

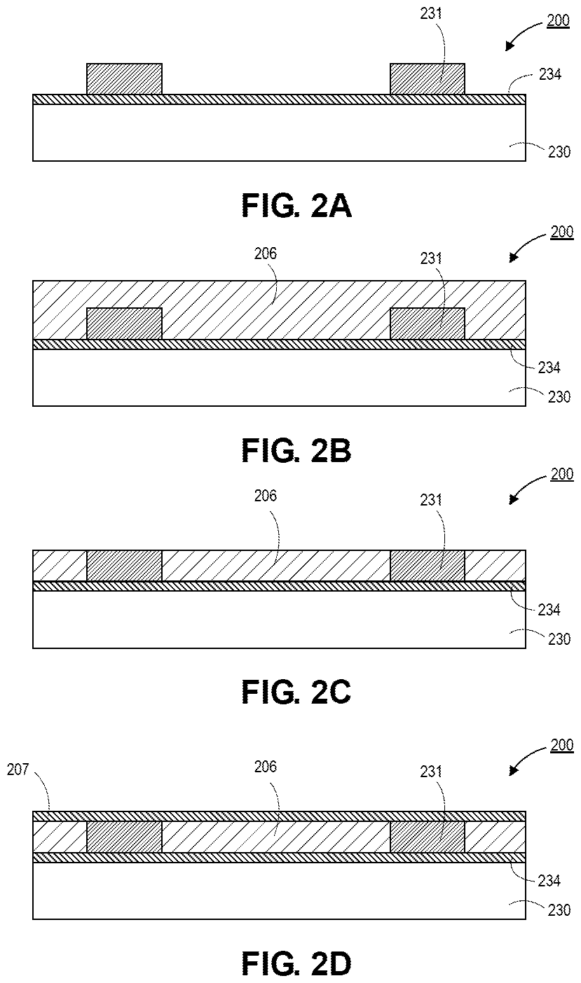

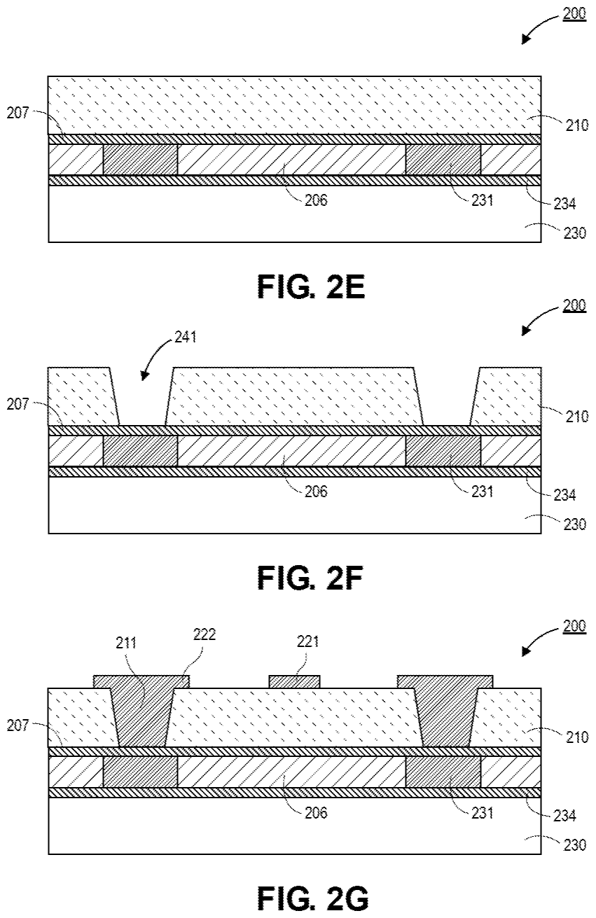

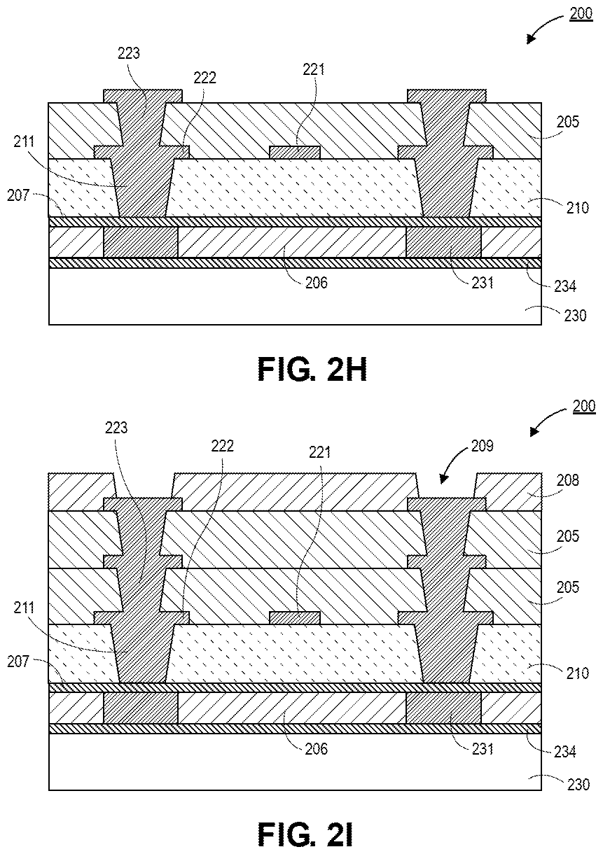

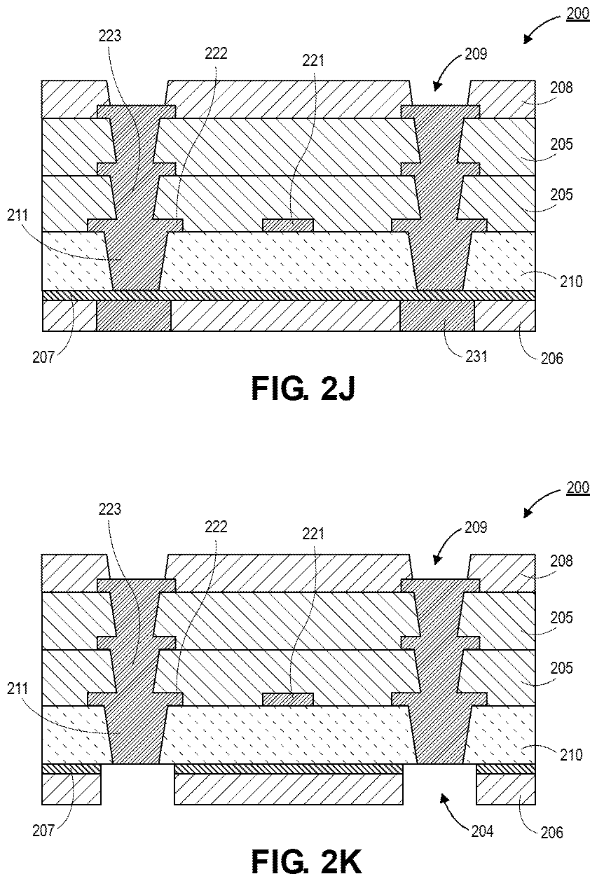

Referring now to FIGS. 2A-2K, a series of cross-sectional illustrations depicting a process for forming a coreless package substrate 200 is shown, in accordance with an embodiment. The package substrate 200 in FIGS. 2A-2K may include a single glass sheet 210 similar to the embodiment shown in FIG. 1A.

Referring now to FIG. 2A, a cross-sectional illustration of the package substrate 200 at a stage of manufacture is shown, in accordance with an embodiment. As shown, the package substrate 200 may be fabricated on a carrier 230. The carrier 230 may be a glass carrier or any other flat and mechanically robust material. In an embodiment, a first adhesive 234 may be provided over the carrier 230. The first adhesive 234 may be any suitable material that secures the package substrate 200 to the carrier 230, and which allows for detaching the carrier 230 at a subsequent processing operation. Additionally, sacrificial bumps 231 may be formed over the first adhesive 234. The sacrificial bumps 231 may comprise copper or any other suitable conductive material.

Referring now to FIG. 2B, a cross-sectional illustration of the package substrate 200 after a first solder resist layer 206 is formed over the sacrificial bumps 231. The first solder resist layer 206 may be disposed with a lamination process, or any other suitable deposition process. A thickness of the first solder resist layer 206 may be greater than a thickness of the sacrificial bumps 231.

Referring now to FIG. 2C, a cross-sectional illustration of the package substrate 200 after the first solder resist 206 is recessed is shown, in accordance with an embodiment. In an embodiment, the first solder resist 206 may be recessed so that the sacrificial bumps 231 are exposed. The first solder resist 206 may be recessed with an etching process, a polishing process (e.g., chemical mechanical polishing (CMP)), or the like.

Referring now to FIG. 2D, a cross-sectional illustration of the package substrate 200 after a second adhesive 207 is applied over the top surface of the package substrate 200 is shown, in accordance with an embodiment. In an embodiment, the second adhesive 207 may be a material that is able to secure a glass sheet to the stack-up. In some embodiments, the second adhesive 207 may be the same material as the first adhesive 234. In other embodiments, the second adhesive 207 may be a buildup film material.

Referring now to FIG. 2E, a cross-sectional illustration of the package substrate 200 after a glass sheet 210 is attached is shown, in accordance with an embodiment. The glass sheet 210 may be attached with a lamination process. For example, a roll-to-roll process may be used to laminate the glass sheet 210 to the second adhesive 207. In other embodiments, the glass sheet 210 may be placed on the second adhesive 207 using a carrier (not shown), or through handling the glass sheet directly. In embodiments, the glass sheet 210 may have a thickness that is suitable for material handling processes (e.g., greater than approximately 100 μm). After the glass sheet 210 is attached to the second adhesive 207, the glass sheet 210 may be thinned to a desired thickness. For example, the ultimate thickness of the glass sheet 210 may be approximately 100 μm or less, approximately 50 μm or less, approximately 20 μm or less, or approximately 5 μm or less.

Referring now to FIG. 2F, a cross-sectional illustration of the package substrate 200 after openings 241 are formed through the glass sheet 210 is shown, in accordance with an embodiment. In an embodiment, the openings 241 may be formed with a laser assisted etching process or any other suitable patterning process. The openings 241 may have sloped sidewalls. The sloped sidewalls may result in a top of the openings 241 being wider than a bottom of the openings 241.

Referring now to FIG. 2G, a cross-sectional illustration of the package substrate 200 after a plating process is used to form vias 211 in the openings 241 is shown, in accordance with an embodiment. In an embodiment, the plating process may further result in the formation of pads 222 and traces 221 over the surface of the glass sheet 210.

Referring now to FIG. 2H, a cross-sectional illustration of the package substrate 200 after a first buildup layer 205 is formed over the glass sheet 210 is shown, in accordance with an embodiment. The first buildup layer 205 may comprise buildup film or the like. In some embodiments the first buildup layer 205 may be a composite with glass fiber or glass cloth reinforcement. In an embodiment, vias 223 may be formed through the first buildup layer 205. Pads 222 may also be formed over the first buildup layer 205. The conductive routing in the buildup layer 205 may be formed with traditional packaging assembly processes, (e.g., SAP or the like).

Referring now to FIG. 2I, a cross-sectional illustration of the package substrate 200 after an additional buildup layer 205 and a second solder resist 208 is formed is shown, in accordance with an embodiment. In an embodiment, two buildup layers 205 are shown over the glass sheet 210. Though, it is to be appreciated that any number of buildup layers 205 may be provided over the glass sheet 210. In an embodiment, SROs 209 may be formed through the second solder resist 208 in order to expose the topmost pads 222.

Referring now to FIG. 2J, a cross-sectional illustration of the package substrate 200 after the core 230 is removed is shown, in accordance with an embodiment. In an embodiment, the core 230 may be removed by deactivating the first adhesive 234. For example, heat or electromagnetic radiation may be used to deactivate the first adhesive 234 and allow removal of the carrier 230 without damaging the package substrate 200.

Referring now to FIG. 2K, a cross-sectional illustration of the package substrate 200 after the sacrificial bumps 231 are removed is shown, in accordance with an embodiment. Removal of the sacrificial bumps 231 may result in SROs 204 being formed. In some embodiments, the exposed portions of the second adhesive 207 may also be removed (e.g., with an etching process). As such, access to the bottom of the vias 211 is provided.

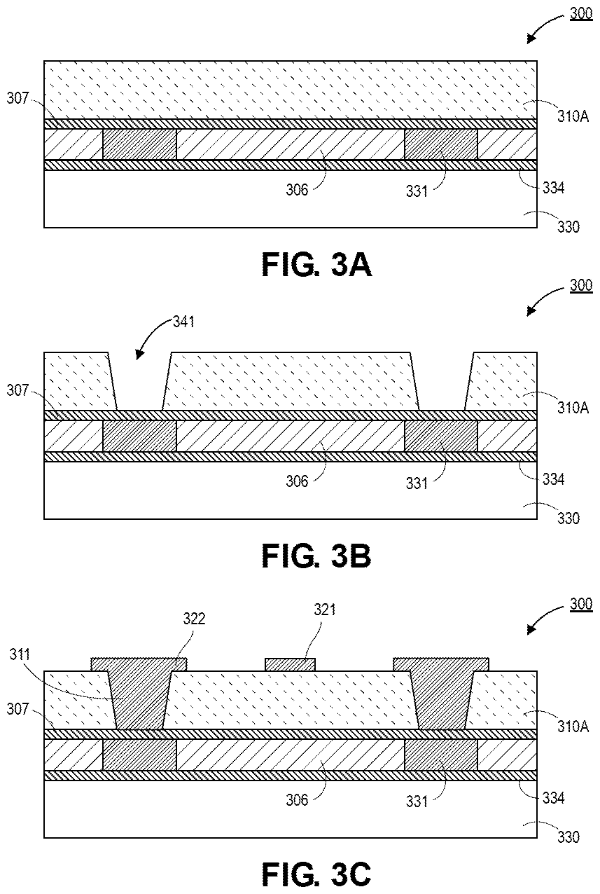

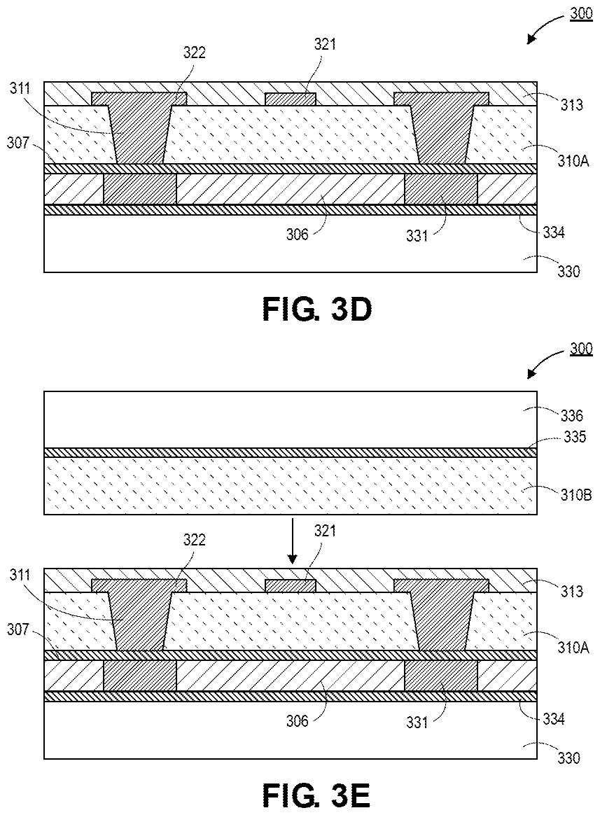

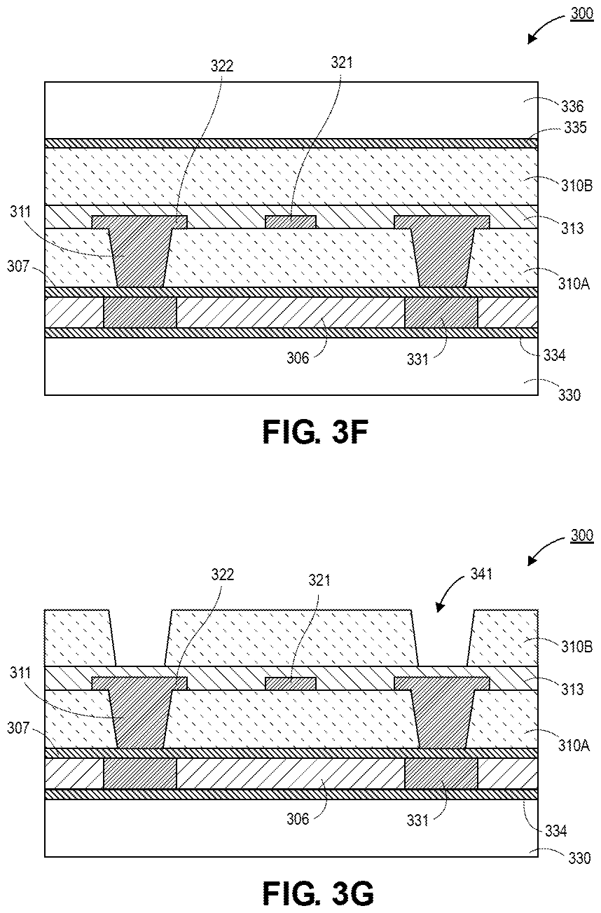

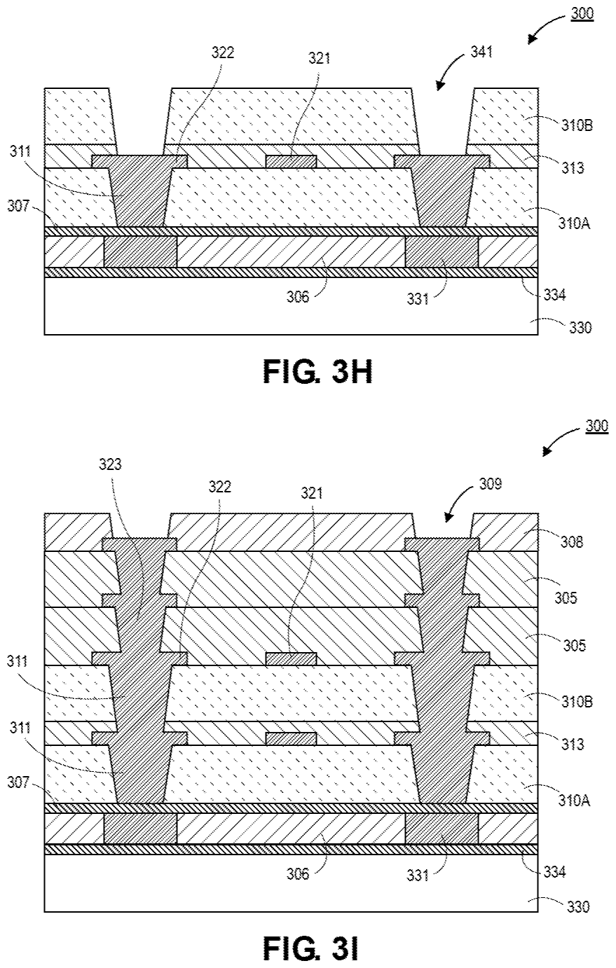

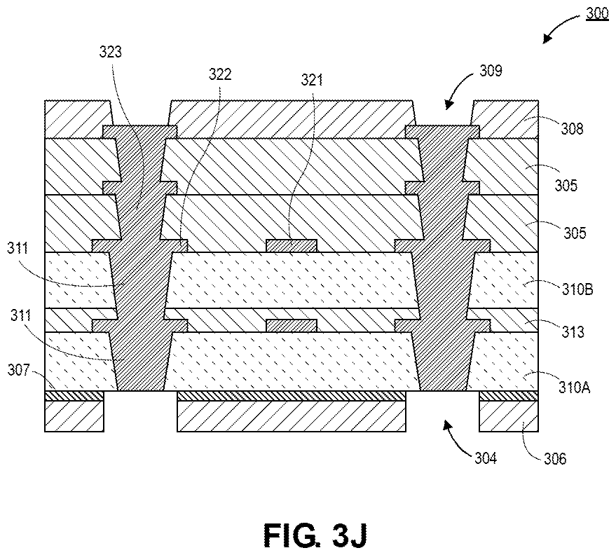

Referring now to FIGS. 3A-3J, a series of cross-sectional illustrations depicting a process for forming a package substrate 300 with a plurality of glass sheets is shown, in accordance with an embodiment. The use of multiple glass sheets may increase the mechanical performance of the package substrate 300. The package substrate 300 in FIGS. 3A-3J may be substantially similar to the package substrate 100 shown in FIG. 1B.

Referring now to FIG. 3A, a cross-sectional illustration of a package substrate 300 at a stage of manufacture is shown, in accordance with an embodiment. In an embodiment, the package substrate 300 shown in FIG. 3A may be formed with processes substantially similar to those described above with respect to FIGS. 2A-2E, and will not be repeated here. At this stage of manufacture, the package substrate 300 comprises a carrier 330, a first adhesive 334, a first solder resist 306, sacrificial bumps 331, a second adhesive 307, and a first glass sheet 310A.

Referring now to FIG. 3B, a cross-sectional illustration of the package substrate 300 after via openings 341 are formed into the first glass sheet 310A is shown, in accordance with an embodiment. In an embodiment, the openings 341 may be formed with a laser assisted etching process or any other suitable patterning process. The openings 341 may have sloped sidewalls. The sloped sidewalls may result in a top of the openings 341 being wider than a bottom of the openings 341.

Referring now to FIG. 3C, a cross-sectional illustration of the package substrate 300 after a plating process is used to form vias 311 in the openings 341 is shown, in accordance with an embodiment. In an embodiment, the plating process may further result in the formation of pads 322 and traces 321 over the surface of the first glass sheet 310A.

Referring now to FIG. 3D, a cross-sectional illustration of the package substrate 300 after a glass-to-glass adhesion layer 313 is formed is shown, in accordance with an embodiment. In an embodiment, the glass-to-glass adhesion layer 313 may be any suitable adhesion material. In some embodiments, the glass-to-glass adhesion layer 313 may comprise buildup film. The glass-to-glass adhesion layer 313 may be applied with a lamination process or the like.

Referring now to FIG. 3E, a cross-sectional illustration of the package substrate 300 during attachment of the second glass sheet 310B is shown, in accordance with an embodiment. The second glass sheet 310B may be attached to a second carrier 336 by an adhesive 335. Though, roll-to-roll or other attachment processes may be used in some embodiments. In an embodiment, the second glass sheet 310B may have a thickness that is approximately 100 μm or less, approximately 50 μm or less, approximately 20 μm or less, or approximately 5 μm or less. In an embodiment, the second glass sheet 310B may have a thickness that is substantially similar to a thickness of the first glass sheet 310A. Though, in other embodiments, the glass sheets 310A and 310B may have different thicknesses.

Referring now to FIG. 3F, a cross-sectional illustration of the package substrate 300 after the second glass sheet 310B is adhered to the glass-to-glass adhesion layer 313 is shown, in accordance with an embodiment. After attaching the second glass sheet 310B, the carrier 336 can be removed.

Referring now to FIG. 3G, a cross-sectional illustration of the package substrate 300 after openings 341 are formed into the second glass sheet 310B is shown, in accordance with an embodiment. In an embodiment, the openings 341 may be formed with a laser assisted patterning process, or any other suitable patterning process.

Referring now to FIG. 3H, a cross-sectional illustration of the package substrate 300 after the openings 341 are transferred into the glass-to-glass adhesive 313 is shown, in accordance with an embodiment. The openings 341 may be extended into the glass-to-glass adhesive 313 with any suitable etching process.

Referring now to FIGS. 3I, a cross-sectional illustration of the package substrate 300 after buildup layers 305 are provided over the second glass sheet 310B is shown, in accordance with an embodiment. The buildup layers and the conductive routing may be formed with any standard package substrate assembly processes. The conductive routing may include traces 321, pads 322, and vias 323. The plating of conductive material may also form vias 311 in the openings 341 of the second glass sheet 310B. In the illustrated embodiment, two buildup layers 305 are shown, but it is to be appreciated that any number of buildup layers 305 may be provided over the second glass sheet 310B. In an embodiment, a second solder resist 308 may be applied over the topmost buildup layer 305. SROs 309 may expose the topmost pads 322.

Referring now to FIG. 3J, a cross-sectional illustration of the package substrate 300 after the carrier 330 is removed is shown, in accordance with an embodiment. After the carrier 330 is removed, the sacrificial bumps 331 can be removed to form SROs 304. The exposed portions of the second adhesive 307 may also be etched to provide access to the bottom of the vias 311 in the first glass sheet 310A.

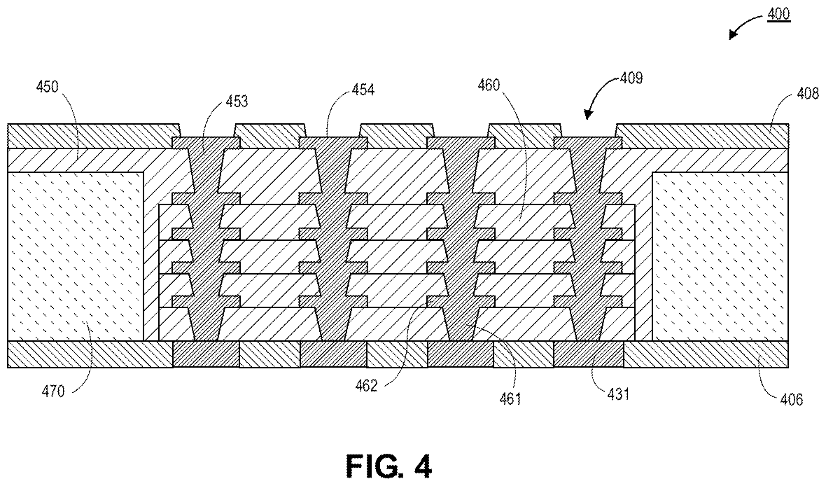

Referring now to FIG. 4, a cross-sectional illustration of a package substrate 400 is shown, in accordance with an additional embodiment. Instead of having a glass sheet for reinforcement, the package substrate 400 includes a glass stiffener 470.

In an embodiment, the package substrate 400 may comprise a first solder resist 406 at a bottom of the package substrate 400. Sacrificial bumps 431 may be provided in the first solder resist 406. Similar to above, the sacrificial bumps 431 may be removed to provide access to the overlying conductive routing. In an embodiment, the overlying conductive routing may be fabricated in a plurality of first buildup layers 460. The first buildup layers 460 may comprise buildup film, or the like. The first buildup layers 460 may include conductive routing (e.g., pads 462, vias 461, traces (not shown), and the like). The conductive routing may be referred to as redistribution layers in some embodiments.

In an embodiment, a glass stiffener 470 may be provided around the plurality of first buildup layers 460. For example, the glass stiffener 470 may be a ring that surrounds the entire perimeter of the plurality of first buildup layers 460. In an embodiment, the glass stiffener 470 may be any suitable glass formulation, such as borosilicate glass or fused silica glass. The glass stiffener 470 may have a thickness that is greater than a combined thickness of the plurality of first buildup layers 460. In other embodiments, the thickness of the glass stiffener 470 may be equal to or less than the combined thickness of the plurality of first buildup layers 460.

In an embodiment, the glass stiffener 470 may be mechanically coupled to the plurality of first buildup layers 460 by a second buildup layer 450. The second buildup layer 450 may be provided over the first buildup layers 460 and the glass stiffener 470. Additionally, the second buildup layer 450 may extend down into a gap that is between an inner surface of the glass stiffener 470 and the outer perimeter of the first buildup layers 460. Vias 453, pads 454, and the like may be provided in the second buildup layer 450 to couple to the conductive routing in the plurality of first buildup layers 460. In an embodiment, a second solder resist 408 may be provided over the second buildup layer 450, and SROs 409 may expose the pads 454.

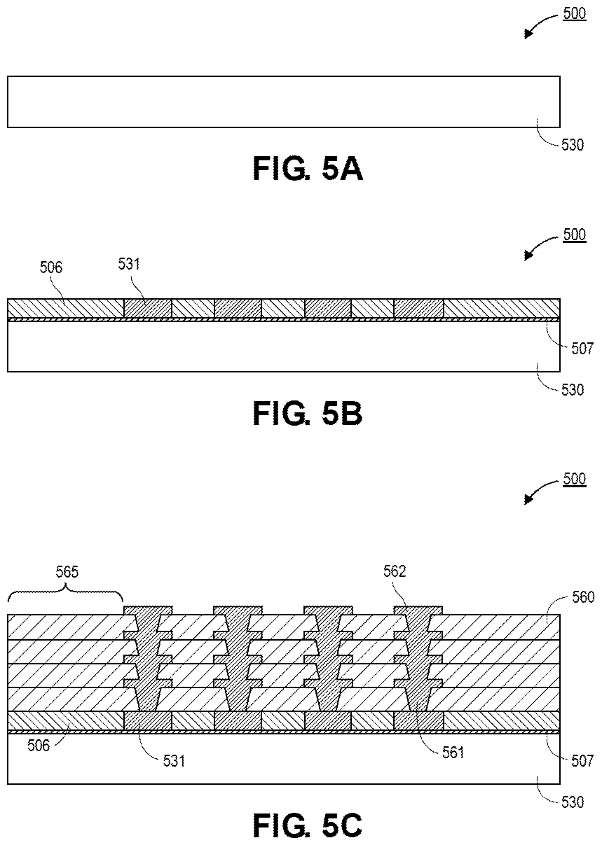

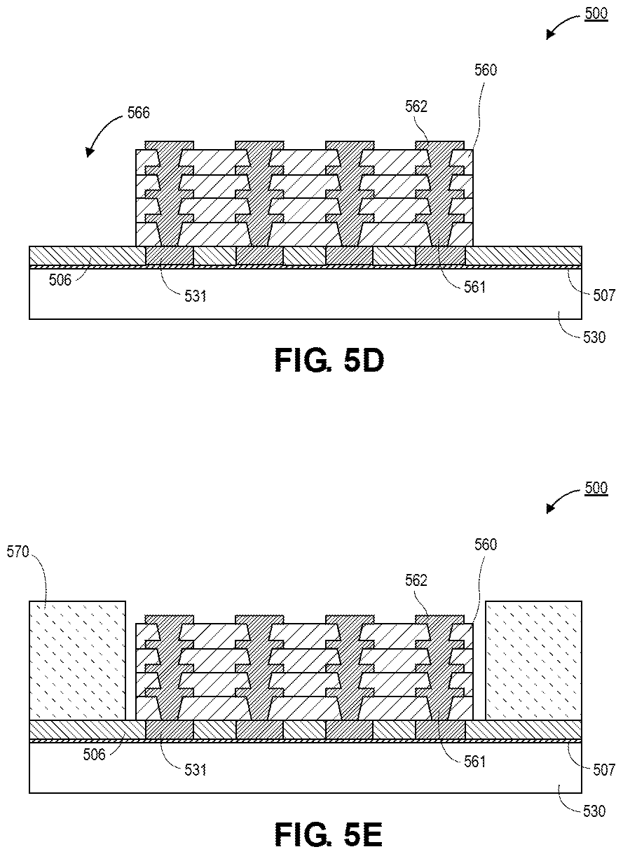

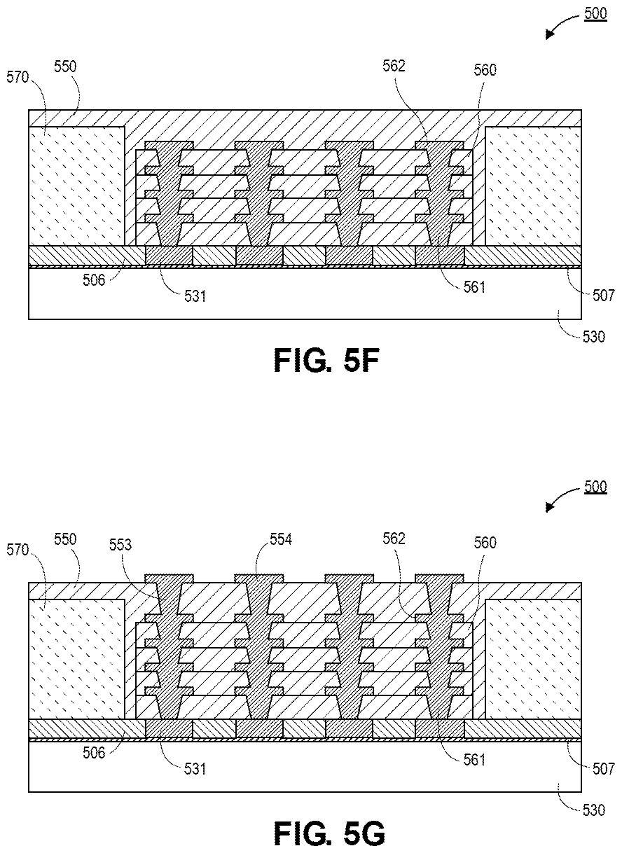

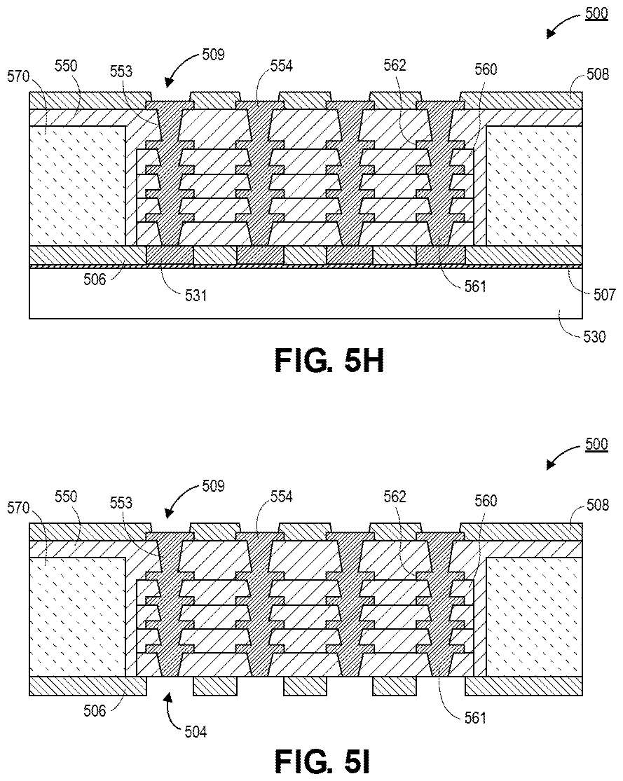

Referring now to FIGS. 5A-5I, a series of cross-sectional illustrations depicting a process for forming a package substrate 500 with a glass stiffener 570 is shown, in accordance with an embodiment. In an embodiment, the package substrate 500 may be substantially similar to the package substrate 400 described with respect to FIG. 4.

Referring now to FIG. 5A, a cross-sectional illustration of the package substrate 500 at a stage of manufacture is shown, in accordance with an embodiment. As shown, the processing begins with the procurement of a carrier 530. The carrier 530 may be a glass carrier, a stainless steel carrier, or any other suitable carrier substrate.

Referring now to FIG. 5B, a cross-sectional illustration of the package substrate 500 after sacrificial bumps 531 and a first solder resist 506 are formed is shown, in accordance with an embodiment. The sacrificial bumps 531 and the first solder resist 506 may be secured to the carrier 530 by an adhesive 507. The first solder resist 506 may be dispensed to a thickness greater than the thickness of the sacrificial bumps 531, and recessed to expose the sacrificial bumps 531.

Referring now to FIG. 5C, a cross-sectional illustration of the package substrate 500 after a plurality of buildup layers 560 are formed over the first solder resist 506 is shown, in accordance with an embodiment. In an embodiment, the buildup layers 560 may be buildup film that is laminated over each other. In an embodiment, conductive routing (e.g., pads 562, vias 561, and traces (not shown)) is fabricated in and on the buildup layers 560 using standard patterning and plating processes. In an embodiment, voided regions 565 may be provided in the buildup layers 560. The voided regions 565 may be regions of the buildup layers 560 where there is no conductive routing. The voided regions 565 will subsequently be removed to provide space for the glass stiffener 570.

Referring now to FIG. 5D, a cross-sectional illustration of the package substrate 500 after the voided regions 565 are removed is shown, in accordance with an embodiment. In an embodiment, the voided regions 565 may be removed with any patterning process. In one embodiment, a laser skiving process is used to remove the voided regions 565. Removal of the voided regions 565 results in the exposure of portions of the first solder resist 506.

Referring now to FIG. 5E, a cross-sectional illustration of the package substrate 500 after the glass stiffener 570 is attached is shown, in accordance with an embodiment. In an embodiment, the glass stiffener 570 is a ring that is placed around an outer perimeter of the buildup layers 560. In an embodiment, a gap is provided between an inner surface of the glass stiffener 570 and an outer edge of the buildup layers 560.

Referring now to FIG. 5F, a cross-sectional illustration of the package substrate 500 after a second buildup layer 550 is applied over the buildup layers 560 and the glass stiffener 570 is shown, in accordance with an embodiment. In an embodiment, the second buildup layer 550 may be the same material as the buildup layers 560. For example, the second buildup layer 550 may comprise a buildup film that is laminated over the top surfaces of the package substrate 500. In an embodiment, the second buildup layer 550 mechanically couples the glass stiffener 570 to the buildup layers 560.

Referring now to FIG. 5G, a cross-sectional illustration of the package substrate 500 after vias 553 and pads 554 are formed in the second buildup layer 550 is shown, in accordance with an embodiment. The vias 553 and pad 554 may be formed with any standard packaging assembly process.

Referring now to FIG. 5H, a cross-sectional illustration of the package substrate 500 after a second solder resist 508 is applied over the second buildup layer 550 is shown, in accordance with an embodiment. The second solder resist 508 may be patterned to have solder resist openings 509 in order to expose the pads 554.

Referring now to FIG. 5I, a cross-sectional illustration of the package substrate 500 after the carrier 530 is removed is shown, in accordance with an embodiment. The carrier 530 may be removed by deactivating the adhesive layer 507 (e.g., by application of heat or electromagnetic radiation). In an embodiment, the sacrificial bumps 531 may then be removed to form SROs 504 in the first solder resist 506 that exposes conductive routing in the buildup layers 560.

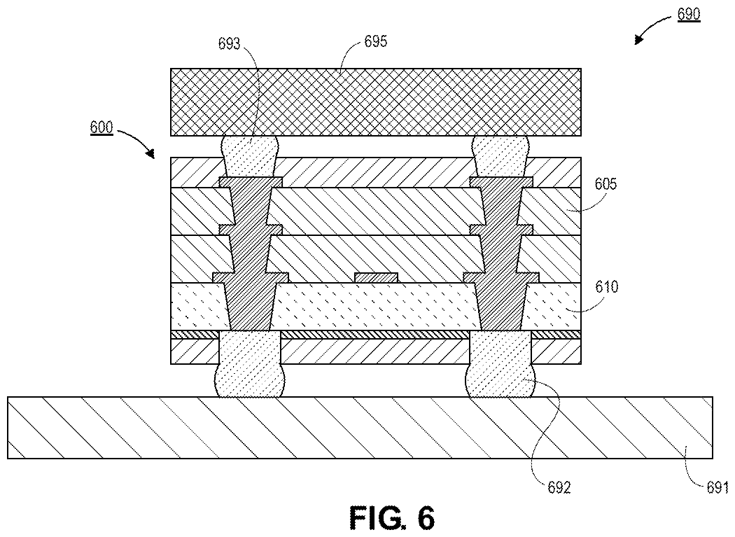

Referring now to FIG. 6, a cross-sectional illustration of a computing system 690 is shown, in accordance with an embodiment. As shown, the computing system 690 comprises a board 691, such as a printed circuit board (PCB). In an embodiment, the board 691 may be coupled to a package substrate 600 by interconnects 692.

In a particular embodiment, the package substrate 600 is a coreless package substrate. The package substrate 600 may be reinforced by a glass structure. In the embodiment shown in FIG. 6, the glass structure is a glass sheet 610. The glass sheet 610 may have a thickness that is approximately 100 μm or less, approximately 50 μm or less, approximately 20 μm or less, or approximately 5 μm or less. Alternatively, the glass structure may be a glass stiffener, similar to the embodiment shown in FIG. 4. One or more buildup layers 605 may be provided over the glass sheet 610 (or within the glass stiffener when a glass stiffener is used). Further, it is to be appreciated that both a glass sheet and a glass stiffener may be used in some embodiments.

In an embodiment, the package substrate 600 may be coupled to one or more dies 695 by interconnects 693. The interconnects 693 may comprise any suitable first level interconnect (FLI) architecture. In an embodiment, the die 695 may be a compute die, such as a central processing unit (CPU), a graphics processing unit (GPU), an XPU, a system on a chip (SoC), an application specific integrated circuit (ASIC), a communications die, or the like. In some embodiments, the die 695 may be a memory die.

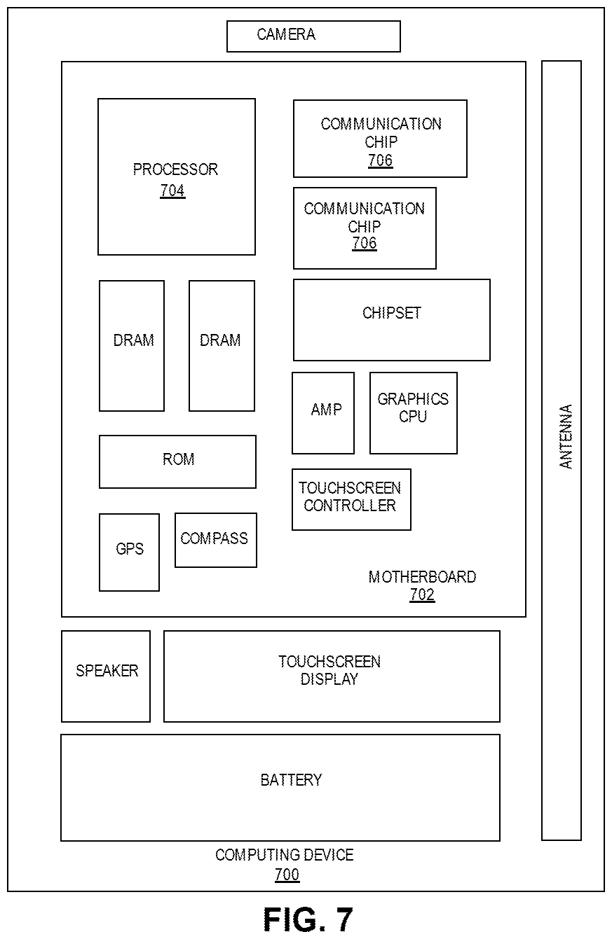

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises a package substrate that is reinforced with an ultrathin glass sheet and/or a glass stiffener, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises a package substrate that is reinforced with an ultrathin glass sheet and/or a glass stiffener, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a first layer, wherein the first layer comprises glass; a second layer over the first layer, wherein the second layer is a buildup film; and an electrically conductive interconnect structure through the first layer and the second layer.

Example 2: the package substrate of Example 1, wherein the package substrate is a coreless package substrate.

Example 3: the package substrate of Example 1 or Example 2, further comprising: a solder resist layer over a surface of the first layer opposite from the second layer.

Example 4: the package substrate of Example 3, further comprising: an adhesive layer between the solder resist layer and the first layer.

Example 5: the package substrate of Examples 1-4, wherein a width of the first layer is substantially equal to a width of the second layer.

Example 6: the package substrate of Examples 1-5, wherein a thickness of the first layer is smaller than a thickness of the second layer.

Example 7: the package substrate of Example 6, wherein the thickness of the first layer is approximately 50 μm or less.

Example 8: the package substrate of Examples 1-7, further comprising: a third layer over the second layer, wherein the third layer comprises glass.

Example 9: the package substrate of Example 8, wherein the electrically conductive interconnect structure passes through the third layer.

Example 10: the package substrate of Examples 1-9, wherein the electrically conductive interconnect structure comprises tapered sidewalls.

Example 11: the package substrate of Examples 1-10, wherein the package substrate is part of a computing system for a personal computer, a server, a mobile device, a tablet, or an automobile.

Example 12: a package substrate, comprising: a plurality of first buildup layers in a stack; a stiffener around a perimeter of the plurality of first buildup layers; and a second buildup layer over the plurality of first buildup layers and the stiffener, and wherein the second buildup layer fills a gap between an inner surface of the stiffener and an outer surface of the plurality of first buildup layers.

Example 13: the package substrate of Example 12, wherein the package substrate is a coreless package substrate.

Example 14: the package substrate of Example 12 or Example 13, wherein the stiffener comprises glass.

Example 15: the package substrate of Examples 12-14, wherein a thickness of the stiffener is greater than a combined thickness of the plurality of first buildup layers.

Example 16: the package substrate of Examples 12-15, wherein the plurality of first buildup layers comprises electrically conductive redistribution layers.

Example 17: the package substrate of Examples 12-16, wherein the package substrate is part of a computing system for a personal computer, a server, a mobile device, a tablet, or an automobile.

Example 18: a computing system, comprising: a board; a package substrate coupled to the board, wherein the package substrate comprises: a glass reinforcement layer; and a plurality of buildup layers with electrically conductive routing; and a die coupled to the package substrate.

Example 19: the computing system of Example 18, wherein the glass reinforcement layer is a stiffener around the plurality of buildup layers or wherein the glass reinforcement layer is a layer below the plurality of buildup layers.

Example 20: the computing system of Example 18 or Example 19, wherein the computing system is part of a personal computer, a server, a mobile device, a tablet, or an automobile.

What is claimed is:

1. A package substrate, comprising:
a first layer, wherein the first layer comprises glass;
a second layer over the first layer, wherein the second layer is a buildup film; and
an electrically conductive interconnect structure through the first layer and the second layer.

2. The package substrate of claim 1, wherein the package substrate is a coreless package substrate.

3. The package substrate of claim 1, further comprising:
a solder resist layer over a surface of the first layer opposite from the second layer.

4. The package substrate of claim 3, further comprising:
an adhesive layer between the solder resist layer and the first layer.

5. The package substrate of claim 1, wherein a width of the first layer is substantially equal to a width of the second layer.

6. The package substrate of claim 1, wherein a thickness of the first layer is smaller than a thickness of the second layer.

7. The package substrate of claim 6, wherein the thickness of the first layer is approximately 50 μm or less.

8. The package substrate of claim 1, further comprising:
a third layer over the second layer, wherein the third layer comprises glass.

9. The package substrate of claim 8, wherein the electrically conductive interconnect structure passes through the third layer.

10. The package substrate of claim 1, wherein the electrically conductive interconnect structure comprises tapered sidewalls.

11. The package substrate of claim 1, wherein the package substrate is part of a computing system for a personal computer, a server, a mobile device, a tablet, or an automobile.

12. A package substrate, comprising:
a plurality of first buildup layers in a stack;
a stiffener around a perimeter of the plurality of first buildup layers; and
a second buildup layer over the plurality of first buildup layers and the stiffener, and wherein the second buildup layer fills a gap between an inner surface of the stiffener and an outer surface of the plurality of first buildup layers.

13. The package substrate of claim 12, wherein the package substrate is a coreless package substrate.

14. The package substrate of claim 12, wherein the stiffener comprises glass.

15. The package substrate of claim 12, wherein a thickness of the stiffener is greater than a combined thickness of the plurality of first buildup layers.

16. The package substrate of claim 12, wherein the plurality of first buildup layers comprises electrically conductive redistribution layers.

17. The package substrate of claim 12, wherein the package substrate is part of a computing system for a personal computer, a server, a mobile device, a tablet, or an automobile.

18. A computing system, comprising:
a board;
a package substrate coupled to the board, wherein the package substrate comprises:
a glass reinforcement layer; and
a plurality of buildup layers with electrically conductive routing; and
a die coupled to the package substrate.

19. The computing system of claim 18, wherein the glass reinforcement layer is a stiffener around the plurality of buildup layers or wherein the glass reinforcement layer is a layer below the plurality of buildup layers.

20. The computing system of claim 18, wherein the computing system is part of a personal computer, a server, a mobile device, a tablet, or an automobile.
